(19) United States
(12) Patent Application Publication
(10) Pub. No.: US 2026/0032876 A1
(43) Pub. Date: Jan. 29, 2026

(54) PASSIVE COOLING DEVICE FOR HEAD-WEARABLE DEVICES, AND SYSTEMS AND METHODS OF USE THEREOF

(71) Applicant: Meta Platforms Technologies, LLC, Menlo Park, CA (US)

(72) Inventors: Min Tao, San Jose, CA (US); Zuoqian Wang, Santa Clara, CA (US); Adam Alan Mudrick, San Carlos, CA (US); Amaury Heresztyn, Berryville, VA (US)

(21) Appl. No.: 19/179,505

(22) Filed: Apr. 15, 2025

Related U.S. Application Data
(60) Provisional application No. 63/634,890, filed on Apr. 16, 2024.

(51) Int. Cl. H05K 7/20; G06F 1/16; G06F 1/20

(52) U.S. Cl. CPC H05K 7/20963; G06F 1/163; G06F 1/203

(57) ABSTRACT

A head-wearable device allowing for passive cooling at a face cover of the head-wearable device is described herein. The head-wearable device comprises a housing and a passive cooling surface cover coupled to a user-facing surface of the housing such that, when the head-wearable device is worn, the passive-cooling surface cover contacts a portion of a user's body. The housing includes one or more electronics components and the user-facing surface. The passive cooling surface cover is configured to (i) absorb heat generated by the one or more electronics components and transferred to the user-facing contact surface and (ii) evaporate a stored moisture using the heat generated by the one or more electronics components to decrease a temperature of the one or more electronics components and/or the passive cooling surface cover.

### CROSS-REFERENCE TO RELATED APPLICATIONS

This application claims the benefit of U.S. Provisional Patent Application No. 63/634,890, filed on Apr. 16, 2024, the disclosures of all of these applications and patents are incorporated by reference herein.

### TECHNICAL FIELD

This disclosure relates generally to a passive cooling device for a head-wearable device, including but not limited to techniques for cooling or reducing temperatures of electronics components of the head-wearable device and/or providing a low temperature contact surface for users.

### BACKGROUND

Head-wearable devices, such as virtual reality or augmented reality headsets, face increasingly substantial thermal management challenges. To render real-time, high-fidelity visuals, there is a reliance on high resolution displays, powerful graphics processing units, and other internal hardware are required, which generate significant heat during operation. Conversely, user comfort and ergonomics demand head-wearable device to be smaller and more compact, which can prevent or hinder effective heat dissipation. Excess heat at the head-wearable devices not only compromises the performance and lifespan of the head-wearable devices' components, but also affects use comfort and safety (e.g., prolonged exposure to a heated device can cause discomfort or even burns, discouraging users from extended use). Conventional cooling methods, such as powerful fans, can be used, however include a number of design constraints, such as an increase in power consumption, use of additional space, an increase in head-wearable device size and/or weight, an increase in generated noises, a reduction in audio quality, etc.

Accordingly, there is a need for improves cooling solutions. As such, there is a need to address one or more of the above-identified challenges. A brief summary of solutions to the issues noted above are described below.

### SUMMARY

The methods, systems, and devices described herein provide cooling solutions that address the drawbacks mentioned above. The methods, systems, and devices described herein provide a passive cooling solution that can be used to optimize component arrangement. The passive cooling solution described herein can integrate materials to ensure both device efficiency and user comfort. The methods, systems, and devices can combine the passive cooling solution with one or more active cooling solutions as described herein. The methods, systems, and devices described herein provides design simplicity (e.g., a solution outside of a housing of an electronic device and does not require additional space inside an enclosure, which can already be complex and compact), power efficiency (e.g., no additional power budget demands), quiet cooling (e.g., no additional noise generated that would otherwise disturb full immersive artificial-reality experiences), a lightweight and thin design, and improved conformability and wearing comfort. The passive cooling solution described herein can be used to optimize power, noise, weight, and shape design of an electronic device (e.g., a head-wearable device).

One example of a passive cooling device for a head-wearable device is described herein. This example head-wearable device includes a housing and a passive cooling surface cover. The housing includes one or more electronics components and a user-facing surface. The passive cooling surface cover is coupled to the user-facing surface of the housing such that, when the head-wearable device is worn, the passive-cooling surface cover contacts a portion of a user's body. The passive cooling surface cover is configured to absorb heat generated by the one or more electronics components and transferred to the user-facing contact surface, and evaporate a stored moisture using the heat generated by the one or more electronics components to decrease a temperature of the one or more electronics components and/or the passive cooling surface cover.

The features and advantages described in the specification are not necessarily all inclusive and, in particular, certain additional features and advantages will be apparent to one of ordinary skill in the art in view of the drawings, specification, and claims. Moreover, it should be noted that the language used in the specification has been principally selected for readability and instructional purposes.

Having summarized the above example aspects, a brief description of the drawings will now be presented.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the figures.

FIGS. 1A-1C illustrate a head-wearable device including a passive cooling surface cover, in accordance with some embodiments.

FIG. 2 illustrates one or more layers of a passive cooling surface cover, in accordance with some embodiments.

FIG. 3 illustrates an example cooling process using a passive cooling surface cover, in accordance with some embodiments.

FIG. 4 illustrates an example graph of the temperature reduction provided by a passive cooling surface cover, in accordance with some embodiments.

FIGS. 5A and 5B show an example method flow chart for forming a head-wearable device including a passive cooling surface cover, in accordance with some embodiments.

FIGS. 6A-6B-2 illustrate example artificial-reality systems, in accordance with some embodiments.

FIGS. 7A-7C illustrate example head-wearable devices, in accordance with some embodiments.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method, or device. Finally, like reference numerals may be used to denote like features throughout the specification and figures.

### DETAILED DESCRIPTION

Numerous details are described herein to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not necessarily been described in exhaustive detail so as to avoid obscuring pertinent aspects of the embodiments described herein.

Embodiments of this disclosure can include or be implemented in conjunction with various types or embodiments of artificial-reality systems. Artificial-reality (AR), as described herein, is any superimposed functionality and or sensory-detectable presentation provided by an artificial-reality system within a user's physical surroundings. Such artificial-realities can include and/or represent virtual reality (VR), augmented reality, mixed artificial-reality (MAR), or some combination and/or variation one of these. For example, a user can perform a swiping in-air hand gesture to cause a song to be skipped by a song-providing API providing playback at, for example, a home speaker. An AR environment, as described herein, includes, but is not limited to, VR environments (including non-immersive, semi-immersive, and fully immersive VR environments); augmented-reality environments (including marker-based augmented-reality environments, markerless augmented-reality environments, location-based augmented-reality environments, and projection-based augmented-reality environments); hybrid reality; and other types of mixed-reality environments.

Artificial-reality content can include completely generated content or generated content combined with captured (e.g., real-world) content. The artificial-reality content can include video, audio, haptic events, or some combination thereof, any of which can be presented in a single channel or in multiple channels (such as stereo video that produces a three-dimensional effect to a viewer). Additionally, in some embodiments, artificial reality can also be associated with applications, products, accessories, services, or some combination thereof, which are used, for example, to create content in an artificial reality and/or are otherwise used in (e.g., to perform activities in) an artificial reality.

A hand gesture, as described herein, can include an in-air gesture, a surface-contact gesture, and or other gestures that can be detected and determined based on movements of a single hand (e.g., a one-handed gesture performed with a user's hand that is detected by one or more sensors of a wearable device (e.g., electromyography (EMG) and/or inertial measurement units (IMU) s of a wrist-wearable device) and/or detected via image data captured by an imaging device of a wearable device (e.g., a camera of a head-wearable device)) or a combination of the user's hands. In-air means, in some embodiments, that the user hand does not contact a surface, object, or portion of an electronic device (e.g., a head-wearable device or other communicatively coupled device, such as the wrist-wearable device), in other words the gesture is performed in open air in 3D space and without contacting a surface, an object, or an electronic device. Surface-contact gestures (contacts at a surface, object, body part of the user, or electronic device) more generally are also contemplated in which a contact (or an intention to contact) is detected at a surface (e.g., a single or double finger tap on a table, on a user's hand or another finger, on the user's leg, a couch, a steering wheel, etc.). The different hand gestures disclosed herein can be detected using image data and/or sensor data (e.g., neuromuscular signals sensed by one or more biopotential sensors (e.g., EMG sensors) or other types of data from other sensors, such as proximity sensors, time-of-flight (ToF) sensors, sensors of an inertial measurement unit, etc.) detected by a wearable device worn by the user and/or other electronic devices in the user's possession (e.g., smartphones, laptops, imaging devices, intermediary devices, and/or other devices described herein).

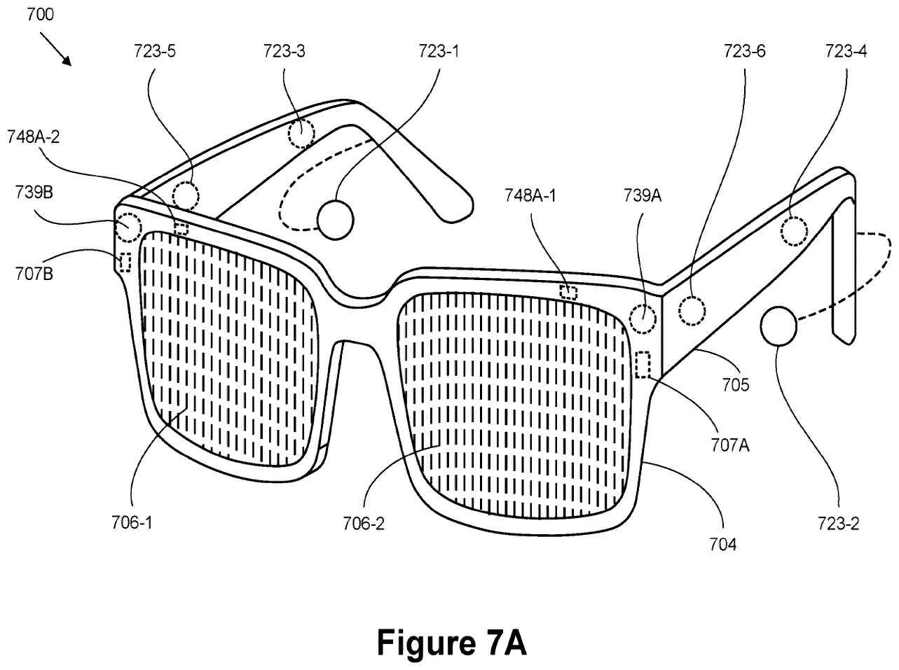

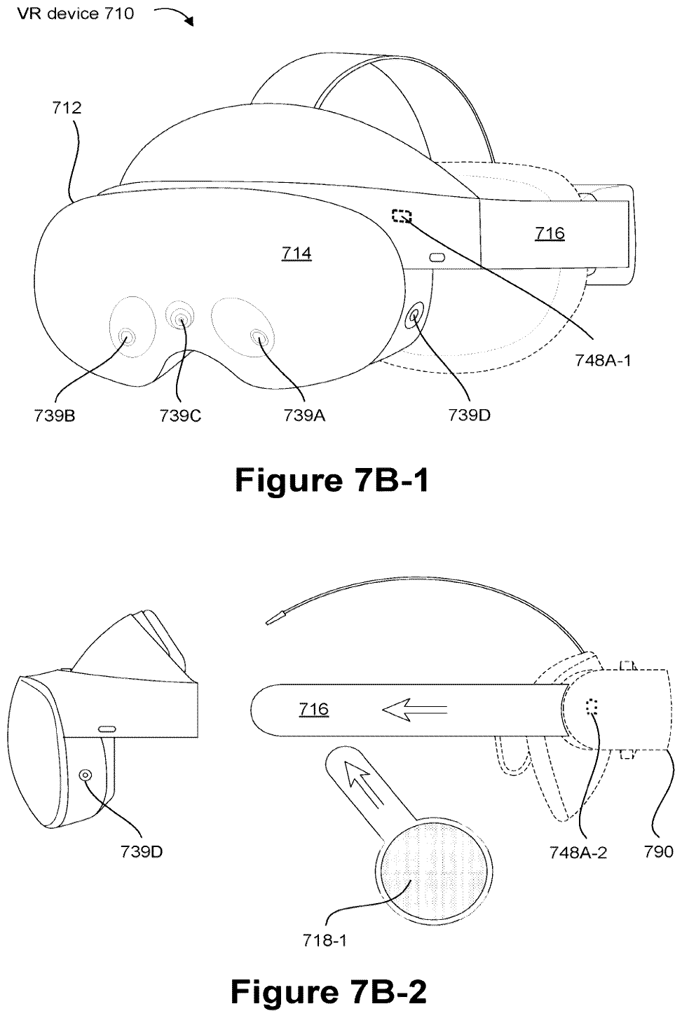

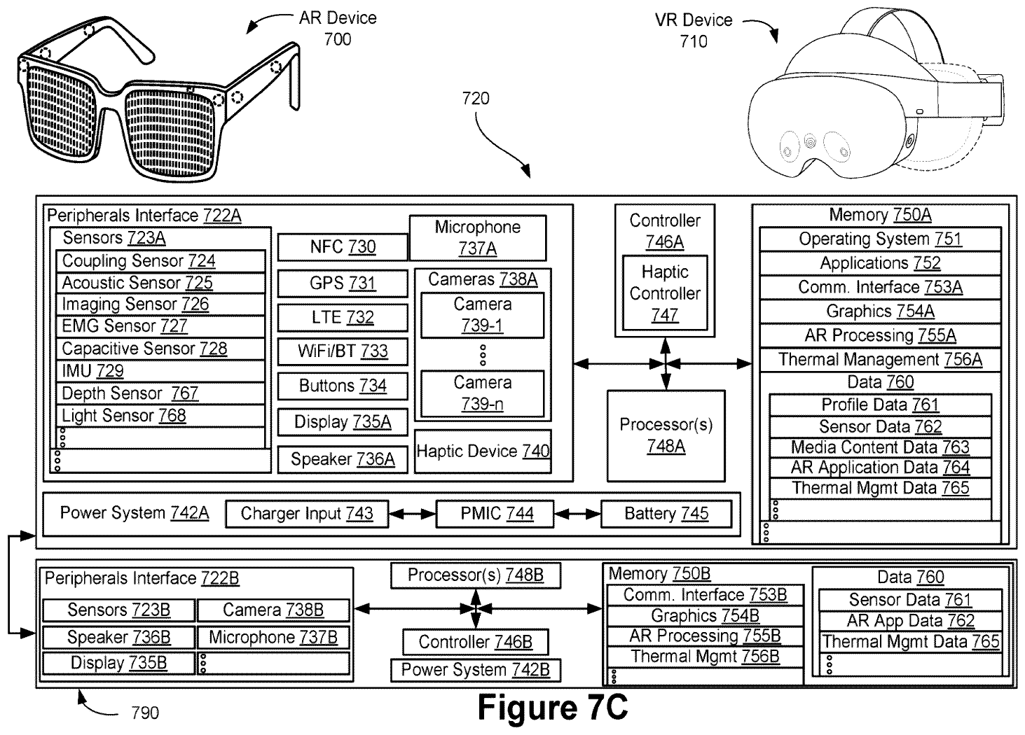

As described herein, a passive cooling device (also referred to as a passive cooling surface cover) is configured to reduce a temperature of one or more electronics components of a head-wearable device (such as an AR device 700 and/or a VR device 710; FIGS. 7A-7C). The passive cooling device is configured to prevent or reduce a user's head from burning or becoming uncomfortable due to increasing operating temperatures of a head-wearable device. The passive cooling device is configured to one or more of improve ergonomic comfort; provide a cooling surface for a user; operate as a face cover interface; provide distributed and local thermal management, and cool at different hot spots, provide an ultra-thin and substantially weightless design, decrease overall operating temperatures (e.g., by 5-10 degrees Celsius). The passive cooling device can include a hydrogel material configured to absorb moisture from the air (or from sweating) and cool the ambient (e.g., surrounding components, the head-wearable device, the user, etc.) using a moisture evaporation process, as well as a swelling to collapse phase transition process. The passive cooling device can be used in conjunction with (smaller) heatsink and/or fan designs to reduce the weight of a device and/or improve user comfort, as well as provide customized local cooling as need. The passive cooling device can be combined with active cooling solutions (e.g., fans, liquid coolers, etc.) to further improve cooling efficiency.

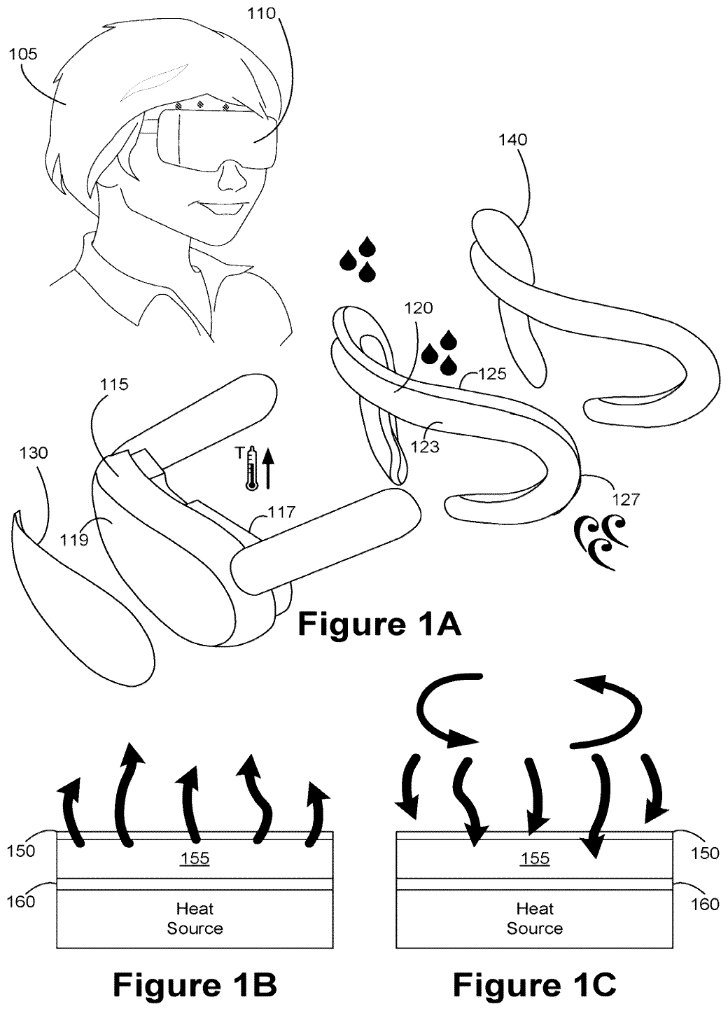

FIGS. 1A-1C illustrate a head-wearable device including a passive cooling surface cover, in accordance with some embodiments. As shown in FIG. 1A, the head-wearable device 110 can include a housing 115 and a passive cooling surface cover 120. The housing 115 can include one or more electronics components (e.g., different components shown and described in reference to FIGS. 7A-7C below) and a user-facing surface 117 (shown adjacent to a thermometer with increasing temperatures). The passive cooling surface cover 129 is configured to couple to the user-facing surface 117 of the housing 115 such that, when the head-wearable device 110 is worn, the passive-cooling surface cover 120 contacts a portion of a user's body.

The passive cooling surface cover 120 can be detachable from the housing 115 or permanently affixed to the housing 115. The passive cooling surface cover 120 includes a device coupling portion 123 configured to couple to the user-facing surface 117 of the housing 115, a user coupling portion 125 configured to contact the portion of the user's body. The device coupling portion 123 of the passive cooling surface cover 120 is configured such that the passive cooling surface cover 120 (or one or more portions thereof) contacts the user-facing surface 117. Alternatively, in some embodiments, the device coupling portion 123 of the passive cooling surface cover 120 is configured such that one or more portions of the passive cooling surface cover 120 are disposed over one or more predetermined portions of the user-facing surface 117 or one or more predetermined portions of the user-facing surface 117 corresponding to placement of one or more heat-dissipating components. For example, one or more portions of the passive cooling surface cover 120 can be applied to different hot spot locations throughout the head-wearable device 110 for more distributed cooling, such as coated on a power supply (e.g., a battery), one or more processors (e.g., a central processing unit, a graphics processing unit, etc.), one or more heatsinks, etc.

In some embodiments, the passive cooling surface cover 120 includes a ventilation portion 127 configured to be exposed to an open environment. The ventilation portion 127 of the passive cooling surface cover 120 can be open sides or outer edges of the passive cooling surface cover 120. The ventilation portion 127 of the passive cooling surface cover 120 allows the passive cooling surface cover 120 to obtain moisture or contact air from the environment as discussed below. The ventilation portion 127 of the passive cooling surface cover 120 can be used with a passive cooling surface cover 120 that cover the user-facing surface 117 or a passive cooling surface cover 120 is disposed over one or more predetermined portions of the user-facing surface 117. Additionally, or alternatively, in some embodiments, the ventilation portion 127 of the passive cooling surface cover 120 can be used with active cooling solutions (e.g., fans, coolers, etc.)

To provide additional comfort to the user 105, the user coupling portion 125 and/or the ventilation portion 127 can be non-smooth or non-continuous surfaces with different topological or micro-structures.

The passive cooling surface cover 120 is configured to absorb heat generated by the one or more electronics components (and transferred to the user-facing contact surface 117). The passive cooling surface cover 120 is further configured to evaporate stored moisture (within the passive cooling surface cover 120) using the heat generated by the one or more electronics components. The evaporated moisture is used to decrease a temperature of the one or more electronics components, user-facing contact surface 117 and/or the passive cooling surface cover 120 (e.g., the user coupling portion 125). The passive cooling surface cover 120 can be configured to absorb moisture (e.g., represented by water droplets and air symbols) from an environment and accumulate absorbed moisture with the stored moisture. For purposes of this disclosure, environment means, in some embodiments, ambient air, ambient temperature, ambient humidity, the user's skin, the user's sweat, and/or other factors external to the passive cooling surface cover 120.

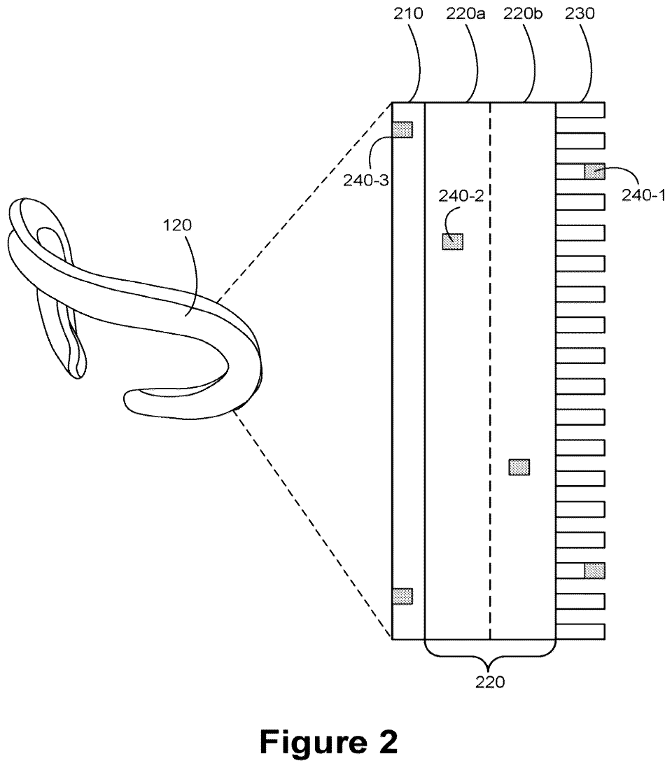

The passive cooling surface cover 120 can include one or more sensors, such as a temperature sensor, a moisture sensor, and a chemical sensor. As shown and described in reference to FIG. 2 below, the one or more sensors can be coupled to a portion of the passive cooling surface cover 120 or disposed within one or more layers. The one or more electronics components included in the housing 115 can include one or more processors. The one or more processors can be configured to receive and monitor sensor data provided by the one or more sensors of the passive cooling surface cover 120. The one or more processors, in accordance with a determination that the sensor data indicates that thermal management criteria are not satisfied, can adjust performance of at least one electronics component of the one or more electronics components. Different adjustments to performance of at least one electronics component of the one or more electronics components can include, but are not limited to, enabling an active cooling device, such as a fan, liquid cooler, etc.; disabling one or more components, such as GPS and imaging device, etc.; decreasing performance of one or more components, such as decreasing CPU performance, decreasing display brightness, etc.; and terminating one or more running applications. In some embodiments, the one or more processors, in accordance with a determination that the sensor data indicates that thermal management criteria are not satisfied, can provide a notification to the user 105 indicating the high temperature and/or one or more mitigation steps (e.g., close an application, move to a shaded location, etc.).

The thermal management criteria include one or more of a head-wearable device thermal threshold, passive cooling surface cover thermal threshold, a passive cooling surface cover volume threshold, an electronics components specific thermal threshold, and a user skin temperature threshold. The above thermal management criteria are not limiting, and other criteria can be used for determining the operating conditions of a head-wearable device 110.

In some embodiments, additional passive cooling layers 130 and 140 can be used to further cool the head-wearable device 110. In some embodiments, a first additional passive cooling layer 130 can be coupled to an exposed surface 119 the housing 115 (opposite the user-facing surface 117). The additional passive cooling layer 130 can be used to cool electronics components adjacent to the exposed surface 119 of the housing 115 and/or provide additional passive cooling for the head-wearable device 110. A second additional passive cooling layer 140 can be coupled to the passive cooling surface cover 120. The second additional passive cooling layer 140 can be used to increase the thickness of the passive cooling surface cover 120, provide an additional structure for storing moisture that can be evaporated, further improve user comfort, and/or increase a surface area for absorbing moisture.

FIGS. 1B and 1C shows an example passive cooling surface 155 absorbing heat and/or moisture. In FIGS. 1B and 1C, the example passive cooling surface 155 is sandwiched between a dustproof film 150 and an insulation film 160. The insulation film 160 is disposed between the example passive cooling surface 155 and a heat source. In FIG. 1B, the example passive cooling surface 155 absorbs heat when heated and volatizes moisture to remove heat from a heat source. In FIG. 1B, the example passive cooling surface 155 absorbs moisture from the air and stores the moisture (when at a low temperature) for use during subsequent heating.

FIG. 2 illustrates one or more layers of a passive cooling surface cover, in accordance with some embodiments. In some embodiments, a passive cooling surface cover 120 includes one or more layers such as an adhesive layer 210 and a cooling material layer 220. The adhesive layer 210 is configured to couple with the user-facing surface 117 (FIG. 1A) and has a predetermined thermal conductivity (e.g., to transfer heat from the electronics components). In some embodiments, the adhesive layer 210 includes thermal interface material. The adhesive layer 210 is configured to contact and/or be close to one or more (heat generating) electronics components of the housing 110.

The cooling material layer 220 can be formed of a single layer. Alternatively, in some embodiments, the cooling material layer 220 includes a plurality of sublayers (e.g., a first sublayer 220a and a second sublayer 220b). The cooling material layer 220 can be one or more hydrogel layers. For example, the cooling material layer 220 can include one or multiple hydrogel-forming polymers (e.g., Polyacrylamide (PAAm), Pol-yvinyl Alcohol (PVA), Polyethylene Glycol (PEG), etc. In some embodiments, the cooling material layer 220 can include Poly (N-isopropylacrylamide) (PNIPAM) and Poly (N-vinylcaprolactam) (PVCL)). In some embodiments, the cooling material layer 220 includes shape memory properties (to further improve user comfort and fit).

The one or more layers of the passive cooling surface cover 120 can include a moisture-wicking layer 230. The cooling material layer 220 is disposed between the adhesive layer 210 and moisture-wicking layer 230. The moisture-wicking layer 230 is configured to contact the portion of the user's body. The moisture-wicking layer can include a porous structure to further absorb and retain moisture (e.g., sweat from a user's skin)

In some embodiment, the passive cooling surface cover 120 is configured to have a predetermined thickness. It has been discovered that effective cooling can be achieved using a passive cooling surface cover 120 with a predetermined thickness of 1 mm-1.5.

As described above in reference to FIGS. 1A-1C, the passive cooling surface cover 120 includes one or more sensors 240-1 through 240-3 (not all sensors are labeled for clarity). The one or more sensors 240 including one or more of a temperature sensor, a moisture sensor, and a chemical sensor. In some embodiments, the one or more sensors 240 are coupled to a surface of the one or more layers and/or within the one or more layers. The one or more sensors 240 can be used to monitor, record, and analyze the behavior of the one or more layers (e.g., the cooling material layer 220) and/or the passive cooling surface cover 120 to improve the effectiveness of thermal management processes and/or for optimization of thermal management processes.

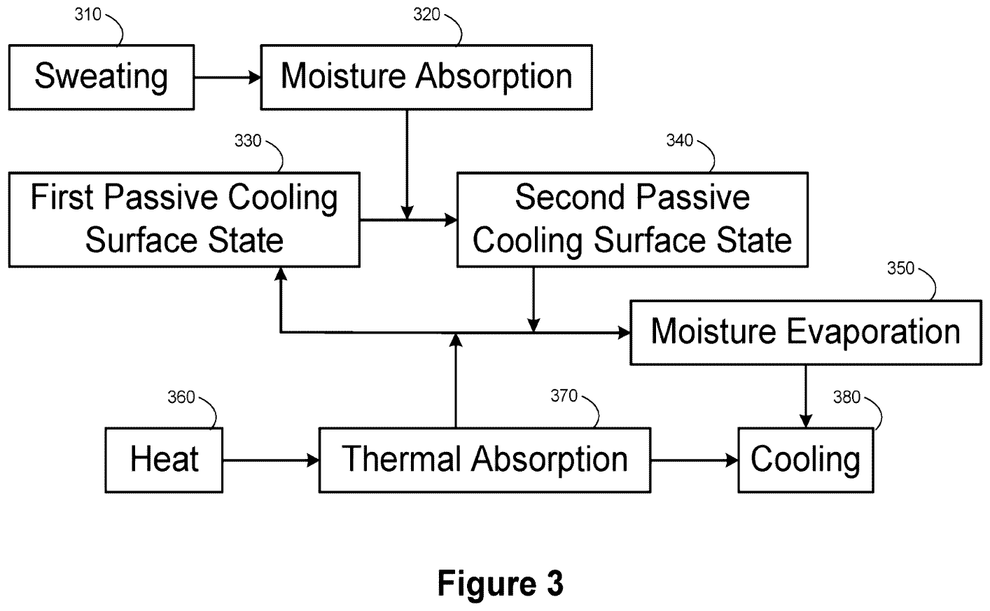

FIG. 3 illustrates an example cooling process using a passive cooling surface cover, in accordance with some embodiments. The cooling process of a passive cooling surface cover 120 (FIGS. 1A-2) can include absorbing moisture 320. The moisture can be absorbed from sweat 310, the air, humidity, and/or other environmental sources. The absorbed moisture is stored at the passive cooling surface cover 120. In some embodiments, the passive cooling surface cover 120 includes at least two states. A first state 330 of the passive cooling surface cover 120 can be a dry or collapsed state (e.g., no moisture is retained within the one or more layers of the passive cooling surface cover 120) and a second state 340 of the passive cooling surface cover 120 can be a swollen or expanded state (e.g., moisture is retained within the one or more layers of the passive cooling surface cover 120).

As moisture is absorbed at step 320, the passive cooling surface cover 120 transitions from the first state 330 (or an intermediary state) to the second state 340. At any point in time, the passive cooling surface cover 120 can absorb heat 360 from any thermally coupled components (e.g., thermal absorption 370). The thermal absorption 370 of the passive cooling surface cover 120 causes the moisture to evaporate (moisture evaporation 350), which, in turn, cools one or more thermally coupled components.

The cooling material layer 220 can have inherently high-water content (e.g., composed of up to around 90% of water content). The high heat capacity of water allows the water of the cooling material layer 220 to absorb a significant amount of heat before it starts to warm up. As such, when a component and/or surface thermally coupled to the passive cooling surface cover 120 generates heat, the passive cooling surface cover 120 absorbs the heat, which leads to a cooling effect on the component and/or surface (as shown by step 380). Additionally, when the passive cooling surface cover 120 absorbs the heat, water retained within the passive cooling surface cover 120 can begin to evaporate (e.g., an endothermic evaporation process). The endothermic evaporation process of the water molecules with the passive cooling surface cover 120 further removes heat from the component and/or surface thermally coupled to the passive cooling surface cover 120, which leading to another cooling effect (as shown by step 380).

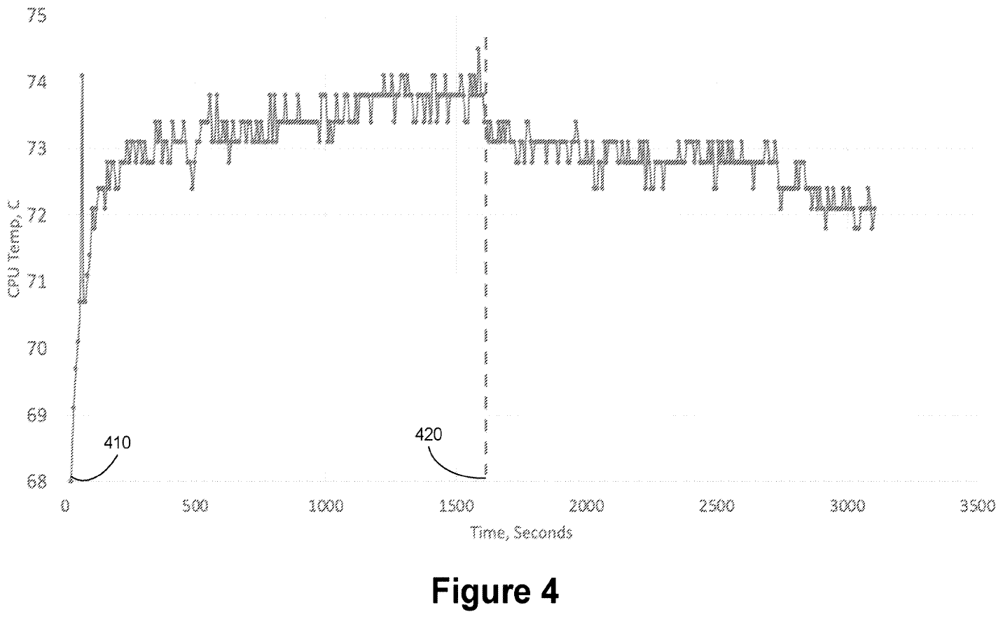

FIG. 4 illustrates an example graph of a central processing unit temperature reduction provided by a passive cooling surface cover, in accordance with some embodiments. In some embodiments, the passive cooling surface cover 120 includes one or more sensors. The one or more sensors are configured to capture sensor data (e.g., a temperature of the passive cooling surface cover 120, a volume and/or a percentage of water in the passive cooling surface cover 120, etc.). In some embodiments, the one or more electronics components of the head-wearable device 110 includes one or more processors. The one or more electronics components also includes at least one processor temperature sensor for capturing sensor data (e.g., a temperature of a central processing unit (CPU) or other processors). The head-wearable device 110 (and/or a communicatively coupled device) monitors the sensor data captured at the at least one sensor and/or the at least one processor temperature sensor.

FIG. 4 illustrates a change in the temperature of a central processing unit of head-wearable device 110, including the passive-cooling surface 120, over time. The head-wearable device 110 is booted-up at a first point in time 410 (e.g., 0 seconds), and the temperature of the CPU rises. As the user interacts with the head-wearable device over a first period of time (e.g., 1600 seconds), the temperature of the CPU continues to rise. When the CPU reaches a temperature of 74.5 degrees Celsius (the temperature of the CPU remaining over 74 degrees Celsius for 400 seconds, etc.) at a second point in time 420, the passive-cooling surface 120 begins to evaporate moisture stored within, which causes the temperature of the CPU to decrease and continue to decrease over a second period of time (e.g., 1500 second).

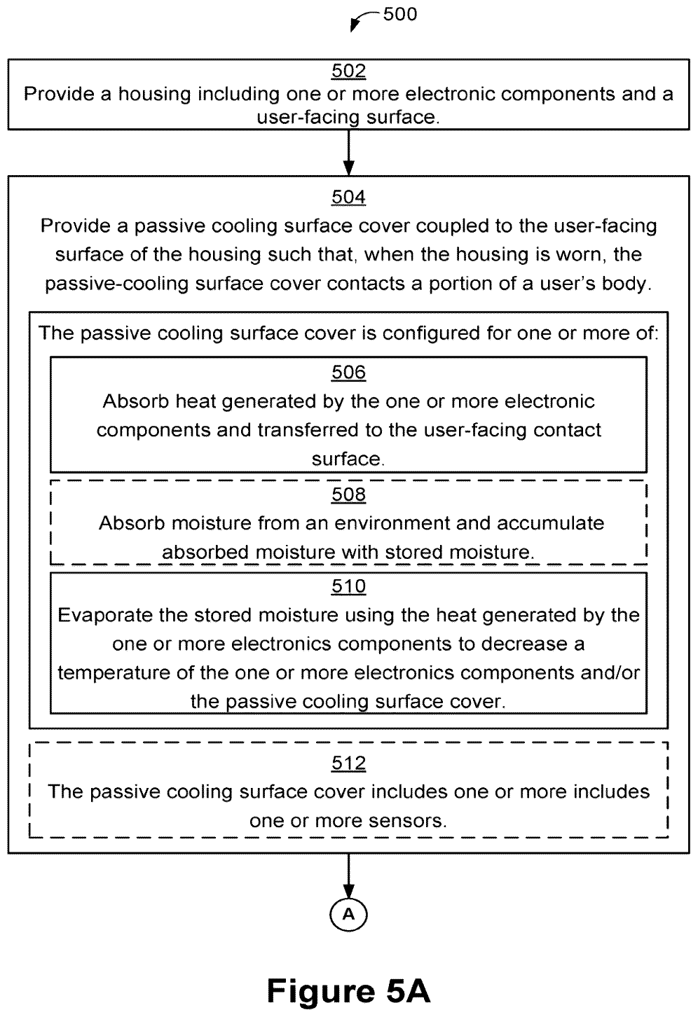

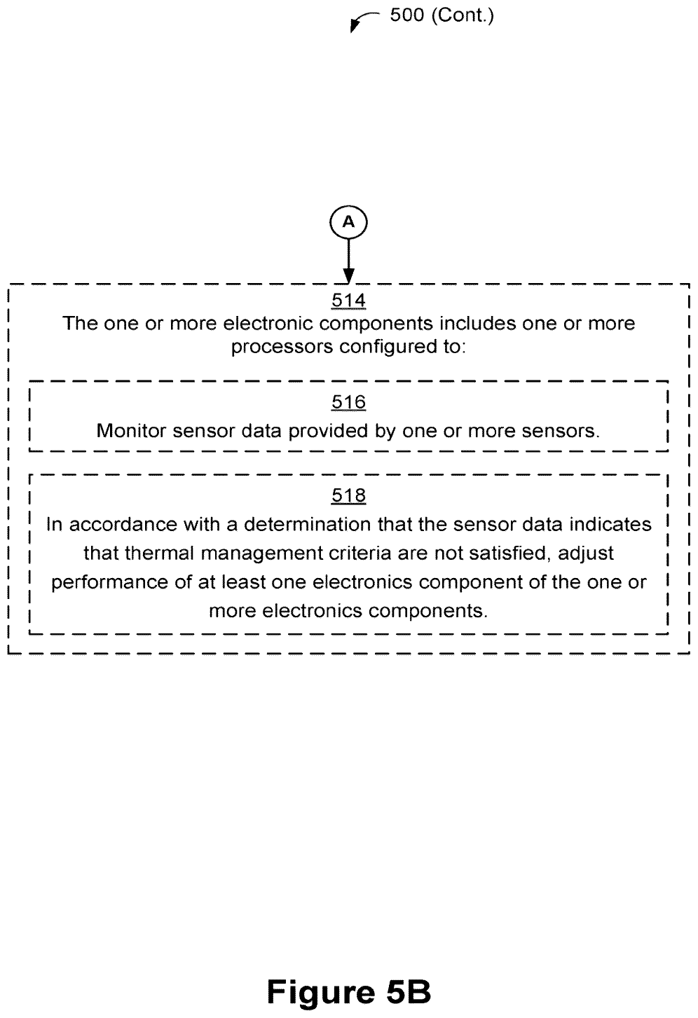

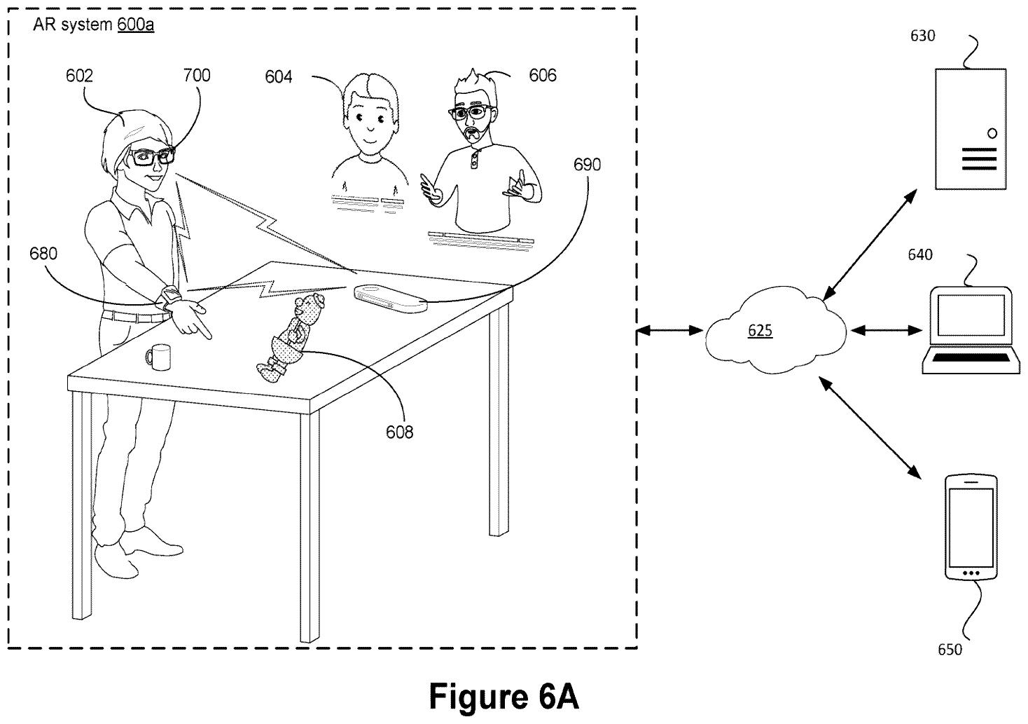

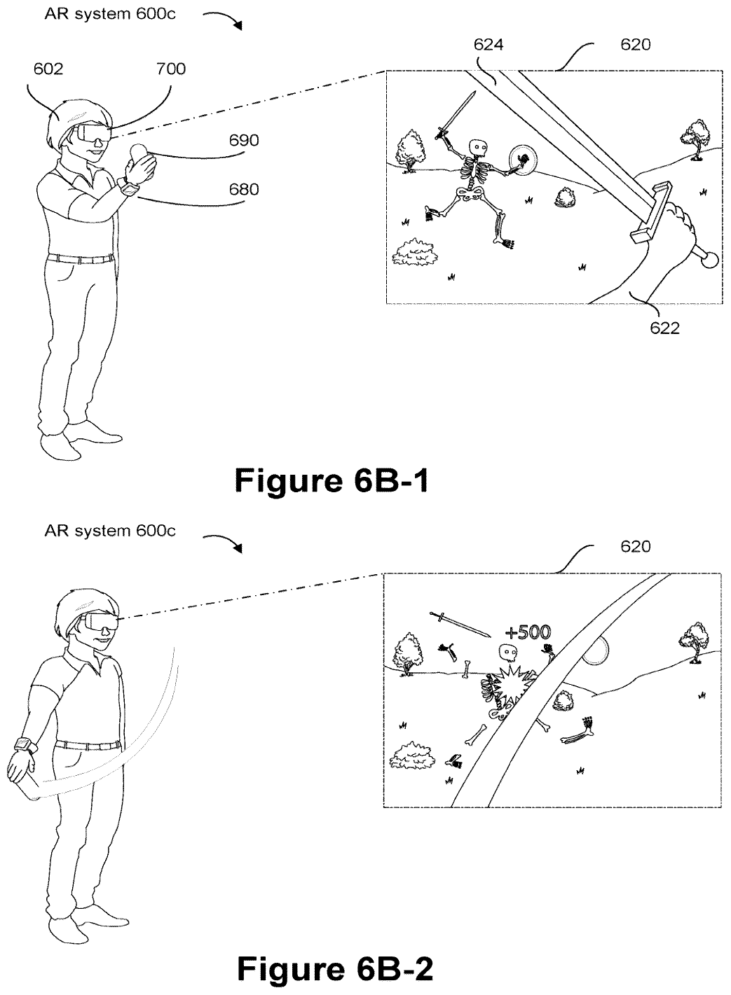

FIGS. 5A-5B illustrate a flow diagram of a method for forming a head-wearable device including a passive cooling surface cover, in accordance with some embodiments. Operations (e.g., steps) of the method 500 can be performed by one or more processors (e.g., central processing unit and/or MCU) of a head-wearable device (e.g., AR device 700 and/or VR device 710). At least some of the operations shown in FIGS. 5A-5B correspond to instructions stored in a computer memory or computer-readable storage medium (e.g., storage, RAM, and/or memory) of the head-wearable device. Operations of the method 500 can be performed by a single device alone or in conjunction with one or more processors and/or hardware components of another communicatively coupled device and/or instructions stored in memory or computer-readable medium of the other device communicatively coupled to the head-wearable device (e.g., any device described and shown in reference to FIG. 6A). In some embodiments, the various operations of the methods described herein are interchangeable and/or optional, and respective operations of the methods are performed by any of the aforementioned devices, systems, or combination of devices and/or systems. For convenience, the method operations will be described below as being performed by particular component or device but should not be construed as limiting the performance of the operation to the particular device in all embodiments.

FIGS. 5A-5B show an example method flow chart for forming a head-wearable device including a passive cooling surface cover, in accordance with some embodiments. In some embodiments, the method 500 includes (502) providing a housing including one or more electronic components and a user-facing surface. The method 500 further includes (504) providing a passive cooling surface cover coupled to the user-facing surface of the housing such that, when the housing is worn, the passive-cooling surface cover contacts a portion of a user's body. The passive cooling surface cover is configured for one or more of: (506) absorbing heat generated by the one or more electronic components and transferred to the user-facing contact surface, (508) absorbing moisture from an environment and accumulate absorbed moisture with stored moisture, in accordance with some embodiments, and (510) evaporating the stored moisture using the heat generated by the one or more electronics components to decrease a temperature of the one or more electronics components and/or the passive cooling surface cover. In some embodiments of the method 500, (512) the passive cooling surface cover includes one or more includes one or more sensors. In some embodiments of the method 500, (514) the one or more electronic components includes one or more processors configured for one or more of: (516) monitoring sensor data provided by one or more sensors and (518), in accordance with a determination that the sensor data indicates that thermal management criteria are not satisfied, adjusting performance of at least one electronics component of the one or more electronics components.

(A1) In accordance with some embodiments, a head-wearable device comprises a housing and a passive cooling surface cover coupled to a user-facing surface of the housing such that, when the head-wearable device is worn, the passive-cooling surface cover contacts a portion of a user's body. The housing includes one or more electronics components and the user-facing surface. The passive cooling surface cover is configured to (i) absorb heat generated by the one or more electronics components and transferred to the user-facing contact surface and (ii) evaporate a stored moisture using the heat generated by the one or more electronics components to decrease a temperature of the one or more electronics components and/or the passive cooling surface cover.

(A2) In some embodiments of A1, the passive cooling surface cover is further configured to absorb moisture from an environment and accumulate absorbed moisture with the stored moisture. In some embodiments, the moisture in from the environment includes moisture in air and/or moisture on the face and/or head of the user.

(A3) In some embodiments of A1-A2, the passive cooling surface cover includes at least two states. The at least two states includes a collapsed state and a swollen state.

(A4) In some embodiments of A1-A3, the passive cooling surface cover includes one or more sensors. The one or more sensors include one or more of a temperature sensor, a moisture sensor, and a chemical sensor.

(A5) In some embodiments of A1-A4, the one or more electronics components includes one or more processors configured to execute one or more programs stored in memory communicatively coupled with the one or more processors. The one or more programs include instructions for: (i) monitoring sensor data provided by the one or more sensors and (ii), in accordance with a determination that the sensor data indicates that thermal management criteria are not satisfied, adjusting performance of at least one electronics component of the one or more electronics components. In some embodiments, adjusting performance of at least one electronics component of the one or more electronics components includes enabling an active cooling device, (e.g., a fan, liquid cooler, etc.), disabling one or more components (e.g., GPS, an imaging device, etc.), and/or decreasing performance of one or more components (e.g., decreasing CPU performance, decreasing display brightness, etc.).

(A6) In some embodiments of A1-A5, the thermal management criteria include one or more of a head-wearable device thermal threshold, passive cooling surface cover thermal threshold, a passive cooling surface cover volume threshold, an electronics components specific thermal threshold, and a user skin temperature threshold.

(A7) In some embodiments of A1-A6, the passive cooling surface cover is disposed over one or more predetermined portions of the user-facing surface, the one or more predetermined portions of the user-facing surface corresponding to placement of one or more heat-dissipating components (e.g., batteries, CPU, heatsink, etc.).

(A8) In some embodiments of A1-A7, the passive cooling surface cover includes one or more layers including a cooling material layer and an adhesive layer. In some embodiments, the adhesive layer includes a thermal interface layer. In some embodiments, the cooling material layer includes shape memory properties.

(A9) In some embodiments A1-A8, the adhesive layer is configured to couple with the user-facing surface and has a predetermined thermal conductivity. In some embodiments, the adhesive layer is configured to transfer heat from the electronics components to the cooling material layer at the predetermined thermal conductivity.

(A10) In some embodiments of A1-A9, the cooling material layer includes a plurality of sublayers. In some embodiments, the cooling material layer is a hydrogel. In some embodiments, the cooling material layer includes one or multiple hydrogel-forming polymers (e.g., Polyacrylamide (PAAm), Pol-yvinyl Alcohol (PVA), Polyethylene Glycol (PEG), Poly (N-isopropylacrylamide) (PNIPAM), and Poly (N-vinylcaprolactam) (PVCL)).

(A11) In some embodiments of A1-A10, the one or more layers includes a moisture-wicking layer. The cooling material layer is disposed between the thermal interface layer and the moisture-wicking layer. The moisture-wicking layer is configured to contact the portion of the user's body.

(A12) In some embodiments of A1-A11, the passive cooling surface cover includes (i) a device coupling portion configured to couple to the user-facing surface of the housing, (ii) a user coupling portion configured to contact the portion of the user's body, and (iii) a ventilation portion configured to be exposed to an open environment.

(A13) In some embodiments of A1-A12, the user coupling portion and/or the ventilation portion are non-smooth or non-continuous surfaces with different topological or micro-structures.

(A14) In some embodiments of A1-A13, the passive cooling surface cover is detachable from the housing or permanently affixed to the housing.

(A15) In some embodiments of A1-A14, the housing includes an exposed surface opposite the user-facing surface. The head-wearable device comprises an additional passive cooling surface cover coupled to the exposed surface.

(B1) In accordance with some embodiments, a non-transitory computer readable storage medium includes instructions that, when executed by at a head-wearable device comprising a housing, including one or more electronics components and a user-facing interface, and a passive cooling surface cover, coupled to the user-facing surface of the housing such that, when the head-wearable device is worn, the passive-cooling surface cover contacts a portion of a user's body, cause the passive cooling surface cover absorb heat generated by the one or more electronics components and transferred to the user-facing contact surface and evaporate a stored moisture using the heat generated by the one or more electronics components to decrease a temperature of the one or more electronics components and/or the passive cooling surface cover.

(B2) In some embodiments of B1, the instructions further cause the computing device to perform operations corresponding to any of A1-A15.

(C1) In accordance with some embodiments, a method of forming an artificial reality headset includes providing a housing including one or more electronic components and a user-facing surface and providing a passive cooling surface cover coupled to the user-facing surface of the housing such that, when the housing is worn, the passive-cooling surface cover contacts a portion of a user's body. The passive cooling surface cover is configured for one or more of: (i) absorbing heat generated by the one or more electronic components and transferred to the user-facing contact surface and (ii) evaporating the stored moisture using the heat generated by the one or more electronics components to decrease a temperature of the one or more electronics components and/or the passive cooling surface cover.

(C2) In some embodiments of B1, the method further includes operations that correspond to any of A1-A15.

(D1) In accordance with some embodiments, a system that includes a head-wearable device, comprising (i) a housing including one or more electronic components and a user-facing surface and (ii) a passive cooling surface cover coupled to the user-facing surface of the housing such that, when the housing is worn, the passive-cooling surface cover contacts a portion of a user's body. The system is configured to cause the passive cooling surface cover to absorb heat generated by the one or more electronics components and transferred to the user-facing contact surface and evaporate a stored moisture using the heat generated by the one or more electronics components to decrease a temperature of the one or more electronics components and/or the passive cooling surface cover.

(D2) In some embodiments of D1, the system is further configured to perform operations corresponding to any of A1-A15.

The devices described above are further detailed below, including systems, wrist-wearable devices, headset devices, and smart textile-based garments. Specific operations described above may occur as a result of specific hardware, such hardware is described in further detail below. The devices described below are not limiting and features on these devices can be removed or additional features can be added to these devices. The different devices can include one or more analogous hardware components. For brevity, analogous devices and components are described below. Any differences in the devices and components are described below in their respective sections.

As described herein, a processor (e.g., a central processing unit (CPU) or microcontroller unit (MCU)), is an electronic component that is responsible for executing instructions and controlling the operation of an electronic device (e.g., a wrist-wearable device 680, a head-wearable device, an HIPD 690, a smart textile-based garment, or other computer system). There are various types of processors that may be used interchangeably or specifically required by embodiments described herein. For example, a processor may be (i) a general processor designed to perform a wide range of tasks, such as running software applications, managing operating systems, and performing arithmetic and logical operations; (ii) a microcontroller designed for specific tasks such as controlling electronic devices, sensors, and motors; (iii) a graphics processing unit (GPU) designed to accelerate the creation and rendering of images, videos, and animations (e.g., virtual-reality animations, such as three-dimensional modeling); (iv) a field-programmable gate array (FPGA) that can be programmed and reconfigured after manufacturing and/or customized to perform specific tasks, such as signal processing, cryptography, and machine learning; (v) a digital signal processor (DSP) designed to perform mathematical operations on signals such as audio, video, and radio waves. One of skill in the art will understand that one or more processors of one or more electronic devices may be used in various embodiments described herein.

As described herein, controllers are electronic components that manage and coordinate the operation of other components within an electronic device (e.g., controlling inputs, processing data, and/or generating outputs). Examples of controllers can include (i) microcontrollers, including small, low-power controllers that are commonly used in embedded systems and Internet of Things (IoT) devices; (ii) programmable logic controllers (PLCs) that may be configured to be used in industrial automation systems to control and monitor manufacturing processes; (iii) system-on-a-chip (SoC) controllers that integrate multiple components such as processors, memory, I/O interfaces, and other peripherals into a single chip; and/or DSPs. As described herein, a graphics module is a component or software module that is designed to handle graphical operations and/or processes, and can include a hardware module and/or a software module.

As described herein, memory refers to electronic components in a computer or electronic device that store data and instructions for the processor to access and manipulate. The devices described herein can include volatile and non-volatile memory. Examples of memory can include (i) random access memory (RAM), such as DRAM, SRAM, DDR RAM or other random access solid state memory devices, configured to store data and instructions temporarily; (ii) read-only memory (ROM) configured to store data and instructions permanently (e.g., one or more portions of system firmware and/or boot loaders); (iii) flash memory, magnetic disk storage devices, optical disk storage devices, other non-volatile solid state storage devices, which can be configured to store data in electronic devices (e.g., universal serial bus (USB) drives, memory cards, and/or solid-state drives (SSDs)); and (iv) cache memory configured to temporarily store frequently accessed data and instructions. Memory, as described herein, can include structured data (e.g., SQL databases, MongoDB databases, GraphQL data, or JSON data). Other examples of memory can include: (i) profile data, including user account data, user settings, and/or other user data stored by the user; (ii) sensor data detected and/or otherwise obtained by one or more sensors; (iii) media content data including stored image data, audio data, documents, and the like; (iv) application data, which can include data collected and/or otherwise obtained and stored during use of an application; and/or any other types of data described herein.

As described herein, a power system of an electronic device is configured to convert incoming electrical power into a form that can be used to operate the device. A power system can include various components, including (i) a power source, which can be an alternating current (AC) adapter or a direct current (DC) adapter power supply; (ii) a charger input that can be configured to use a wired and/or wireless connection (which may be part of a peripheral interface, such as a USB, micro-USB interface, near-field magnetic coupling, magnetic inductive and magnetic resonance charging, and/or radio frequency (RF) charging); (iii) a power-management integrated circuit, configured to distribute power to various components of the device and ensure that the device operates within safe limits (e.g., regulating voltage, controlling current flow, and/or managing heat dissipation); and/or (iv) a battery configured to store power to provide usable power to components of one or more electronic devices.

As described herein, peripheral interfaces are electronic components (e.g., of electronic devices) that allow electronic devices to communicate with other devices or peripherals and can provide a means for input and output of data and signals. Examples of peripheral interfaces can include (i) USB and/or micro-USB interfaces configured for connecting devices to an electronic device; (ii) Bluetooth interfaces configured to allow devices to communicate with each other, including Bluetooth low energy (BLE); (iii) near-field communication (NFC) interfaces configured to be short-range wireless interfaces for operations such as access control; (iv) POGO pins, which may be small, spring-loaded pins configured to provide a charging interface; (v) wireless charging interfaces; (vi) global-position system (GPS) interfaces; (vii) Wi-Fi interfaces for providing a connection between a device and a wireless network; and (viii) sensor interfaces.

As described herein, sensors are electronic components (e.g., in and/or otherwise in electronic communication with electronic devices, such as wearable devices) configured to detect physical and environmental changes and generate electrical signals. Examples of sensors can include (i) imaging sensors for collecting imaging data (e.g., including one or more cameras disposed on a respective electronic device); (ii) biopotential-signal sensors; (iii) inertial measurement unit (e.g., IMUs) for detecting, for example, angular rate, force, magnetic field, and/or changes in acceleration; (iv) heart rate sensors for measuring a user's heart rate; (v) SpO2 sensors for measuring blood oxygen saturation and/or other biometric data of a user; (vi) capacitive sensors for detecting changes in potential at a portion of a user's body (e.g., a sensor-skin interface) and/or the proximity of other devices or objects; and (vii) light sensors (e.g., ToF sensors, infrared light sensors, or visible light sensors), and/or sensors for sensing data from the user or the user's environment. As described herein biopotential-signal-sensing components are devices used to measure electrical activity within the body (e.g., biopotential-signal sensors). Some types of biopotential-signal sensors include: (i) electroencephalography (EEG) sensors configured to measure electrical activity in the brain to diagnose neurological disorders; (ii) electrocardiogramar (ECG or EKG) sensors configured to measure electrical activity of the heart to diagnose heart problems; (iii) electromyography (EMG) sensors configured to measure the electrical activity of muscles and diagnose neuromuscular disorders; (iv) electrooculography (EOG) sensors configured to measure the electrical activity of eye muscles to detect eye movement and diagnose eye disorders.

As described herein, an application stored in memory of an electronic device (e.g., software) includes instructions stored in the memory. Examples of such applications include (i) games; (ii) word processors; (iii) messaging applications; (iv) media-streaming applications; (v) financial applications; (vi) calendars; (vii) clocks; (viii) web browsers; (ix) social media applications, (x) camera applications, (xi) web-based applications; (xii) health applications; (xiii) artificial-reality (AR) applications, and/or any other applications that can be stored in memory. The applications can operate in conjunction with data and/or one or more components of a device or communicatively coupled devices to perform one or more operations and/or functions.

As described herein, communication interface modules can include hardware and/or software capable of data communications using any of a variety of custom or standard wireless protocols (e.g., IEEE 802.15.4, Wi-Fi, ZigBee, 6LoWPAN, Thread, Z-Wave, Bluetooth Smart, ISA100.11a, WirelessHART, or MiWi), custom or standard wired protocols (e.g., Ethernet or HomePlug), and/or any other suitable communication protocol, including communication protocols not yet developed as of the filing date of this document. A communication interface is a mechanism that enables different systems or devices to exchange information and data with each other, including hardware, software, or a combination of both hardware and software. For example, a communication interface can refer to a physical connector and/or port on a device that enables communication with other devices (e.g., USB, Ethernet, HDMI, or Bluetooth). In some embodiments, a communication interface can refer to a software layer that enables different software programs to communicate with each other (e.g., application programming interfaces (APIs) and protocols such as HTTP and TCP/IP).

As described herein, a graphics module is a component or software module that is designed to handle graphical operations and/or processes, and can include a hardware module and/or a software module.

As described herein, non-transitory computer-readable storage media are physical devices or storage medium that can be used to store electronic data in a non-transitory form (e.g., such that the data is stored permanently until it is intentionally deleted or modified).

### Example AR Systems

FIGS. 6A-6B-2 illustrate example artificial-reality systems, in accordance with some embodiments. FIG. 6A shows a first AR system 600a and first example user interactions using a wrist-wearable device 680, a head-wearable device (e.g., AR device 700), and/or a handheld intermediary processing device (HIPD) 690. FIGS. 6B-1 and 6B-2 show a third AR system 600b and third example user interactions using a wrist-wearable device 680, a head-wearable device (e.g., virtual-reality (VR) device 710), and/or an HIPD 690. As the skilled artisan will appreciate upon reading the descriptions provided herein, the above-example AR systems (described in detail below) can perform various functions and/or operations described above with reference to FIGS. 1A-5.

The head-wearable devices and their constituent components are described below in reference to FIGS. 7A-7D. The wrist-wearable device 680, the head-wearable devices, and/or the HIPD 690 can communicatively couple via a network 625 (e.g., cellular, near field, Wi-Fi, personal area network, wireless LAN, etc.). Additionally, the wrist-wearable device 680, the head-wearable devices, and/or the HIPD 690 can also communicatively couple with one or more servers 630, computers 640 (e.g., laptops, computers, etc.), mobile devices 650 (e.g., smartphones, tablets, etc.), and/or other electronic devices via the network 625 (e.g., cellular, near field, Wi-Fi, personal area network, wireless LAN, etc.

Turning to FIG. 6A, a user 602 is shown wearing the wrist-wearable device 680 and the AR device 700, and having the HIPD 690 on their desk. The wrist-wearable device 680, the AR device 700, and the HIPD 690 facilitate user interaction with an AR environment. In particular, as shown by the first AR system 600a, the wrist-wearable device 680, the AR device 700, and/or the HIPD 690 cause presentation of one or more avatars 604, digital representations of contacts 606, and virtual objects 608. As discussed below, the user 602 can interact with the one or more avatars 604, digital representations of the contacts 606, and virtual objects 608 via the wrist-wearable device 680, the AR device 700, and/or the HIPD 690.

The user 602 can use any of the wrist-wearable device 680, the AR device 700, and/or the HIPD 690 to provide user inputs. For example, the user 602 can perform one or more hand gestures that are detected by the wrist-wearable device 680 (e.g., using one or more EMG sensors and/or IMUs) and/or AR device 700 (e.g., using one or more image sensors or cameras, described below in reference to FIGS. 7A-7B) to provide a user input. Alternatively, or additionally, the user 602 can provide a user input via one or more touch surfaces of the wrist-wearable device 680, the AR device 700, and/or the HIPD 690, and/or voice commands captured by a microphone of the wrist-wearable device 680, the AR device 700, and/or the HIPD 690. In some embodiments, the wrist-wearable device 680, the AR device 700, and/or the HIPD 690 include a digital assistant to help the user in providing a user input (e.g., completing a sequence of operations, suggesting different operations or commands, providing reminders, confirming a command). In some embodiments, the user 602 can provide a user input via one or more facial gestures and/or facial expressions. For example, cameras of the wrist-wearable device 680, the AR device 700, and/or the HIPD 690 can track the user 602's eyes for navigating a user interface.

The wrist-wearable device 680, the AR device 700, and/or the HIPD 690 can operate alone or in conjunction to allow the user 602 to interact with the AR environment. In some embodiments, the HIPD 690 is configured to operate as a central hub or control center for the wrist-wearable device 680, the AR device 700, and/or another communicatively coupled device. For example, the user 602 can provide an input to interact with the AR environment at any of the wrist-wearable device 680, the AR device 700, and/or the HIPD 690, and the HIPD 690 can identify one or more back-end and front-end tasks to cause the performance of the requested interaction and distribute instructions to cause the performance of the one or more back-end and front-end tasks at the wrist-wearable device 680, the AR device 700, and/or the HIPD 690. In some embodiments, a back-end task is a background-processing task that is not perceptible by the user (e.g., rendering content, decompression, compression, etc.), and a front-end task is a user-facing task that is perceptible to the user (e.g., presenting information to the user, providing feedback to the user, etc.)). As described below in reference to Figures [% %] A-[% %] B, the HIPD 690 can perform the back-end tasks and provide the wrist-wearable device 680 and/or the AR device 700 operational data corresponding to the performed back-end tasks such that the wrist-wearable device 680 and/or the AR device 700 can perform the front-end tasks. In this way, the HIPD 690, which has more computational resources and greater thermal headroom than the wrist-wearable device 680 and/or the AR device 700, performs computationally intensive tasks and reduces the computer resource utilization and/or power usage of the wrist-wearable device 680 and/or the AR device 700.

In the example shown by the first AR system 600a, the HIPD 690 identifies one or more back-end tasks and front-end tasks associated with a user request to initiate an AR video call with one or more other users (represented by the avatar 604 and the digital representation of the contact 606) and distributes instructions to cause the performance of the one or more back-end tasks and front-end tasks. In particular, the HIPD 690 performs back-end tasks for processing and/or rendering image data (and other data) associated with the AR video call and provides operational data associated with the performed back-end tasks to the AR device 700 such that the AR device 700 performs front-end tasks for presenting the AR video call (e.g., presenting the avatar 604 and the digital representation of the contact 606).

In some embodiments, the HIPD 690 can operate as a focal or anchor point for causing the presentation of information. This allows the user 602 to be generally aware of where information is presented. For example, as shown in the first AR system 600a, the avatar 604 and the digital representation of the contact 606 are presented above the HIPD 690. In particular, the HIPD 690 and the AR device 700 operate in conjunction to determine a location for presenting the avatar 604 and the digital representation of the contact 606. In some embodiments, information can be presented within a predetermined distance from the HIPD 690 (e.g., within five meters). For example, as shown in the first AR system 600a, virtual object 608 is presented on the desk some distance from the HIPD 690. Similar to the above example, the HIPD 690 and the AR device 700 can operate in conjunction to determine a location for presenting the virtual object 608. Alternatively, in some embodiments, presentation of information is not bound by the HIPD 690. More specifically, the avatar 604, the digital representation of the contact 606, and the virtual object 608 do not have to be presented within a predetermined distance of the HIPD 690.

User inputs provided at the wrist-wearable device 680, the AR device 700, and/or the HIPD 690 are coordinated such that the user can use any device to initiate, continue, and/or complete an operation. For example, the user 602 can provide a user input to the AR device 700 to cause the AR device 700 to present the virtual object 608 and, while the virtual object 608 is presented by the AR device 700, the user 602 can provide one or more hand gestures via the wrist-wearable device 680 to interact and/or manipulate the virtual object 608.

In some embodiments, the user 602 initiates, via a user input, an application on the wrist-wearable device 680, the AR device 700, and/or the HIPD 690 that causes the application to initiate on at least one device. For example, in the second AR system 600b the user 602 performs a hand gesture associated with a command for initiating a messaging application (represented by messaging user interface 612); the wrist-wearable device 680 detects the hand gesture; and, based on a determination that the user 602 is wearing AR device 700, causes the AR device 700 to present a messaging user interface 612 of the messaging application. The AR device 700 can present the messaging user interface 612 to the user 602 via its display (e.g., as shown by user 602's field of view 610). In some embodiments, the application is initiated and can be run on the device (e.g., the wrist-wearable device 680, the AR device 700, and/or the HIPD 690) that detects the user input to initiate the application, and the device provides another device operational data to cause the presentation of the messaging application. For example, the wrist-wearable device 680 can detect the user input to initiate a messaging application, initiate and run the messaging application, and provide operational data to the AR device 700 and/or the HIPD 690 to cause presentation of the messaging application. Alternatively, the application can be initiated and run at a device other than the device that detected the user input. For example, the wrist-wearable device 680 can detect the hand gesture associated with initiating the messaging application and cause the HIPD 690 to run the messaging application and coordinate the presentation of the messaging application.

Further, the user 602 can provide a user input provided at the wrist-wearable device 680, the AR device 700, and/or the HIPD 690 to continue and/or complete an operation initiated at another device. For example, after initiating the messaging application via the wrist-wearable device 680 and while the AR device 700 presents the messaging user interface 612, the user 602 can provide an input at the HIPD 690 to prepare a response (e.g., shown by the swipe gesture performed on the HIPD 690). The user 602's gestures performed on the HIPD 690 can be provided and/or displayed on another device. For example, the user 602's swipe gestures performed on the HIPD 690 are displayed on a virtual keyboard of the messaging user interface 612 displayed by the AR device 700.

In some embodiments, the wrist-wearable device 680, the AR device 700, the HIPD 690, and/or other communicatively coupled devices can present one or more notifications to the user 602. The notification can be an indication of a new message, an incoming call, an application update, a status update, etc. The user 602 can select the notification via the wrist-wearable device 680, the AR device 700, or the HIPD 690 and cause presentation of an application or operation associated with the notification on at least one device. For example, the user 602 can receive a notification that a message was received at the wrist-wearable device 680, the AR device 700, the HIPD 690, and/or other communicatively coupled device and provide a user input at the wrist-wearable device 680, the AR device 700, and/or the HIPD 690 to review the notification, and the device detecting the user input can cause an application associated with the notification to be initiated and/or presented at the wrist-wearable device 680, the AR device 700, and/or the HIPD 690.

While the above example describes coordinated inputs used to interact with a messaging application, the skilled artisan will appreciate upon reading the descriptions that user inputs can be coordinated to interact with any number of applications including, but not limited to, gaming applications, social media applications, camera applications, web-based applications, financial applications, etc. For example, the AR device 700 can present to the user 602 game application data and the HIPD 690 can use a controller to provide inputs to the game. Similarly, the user 602 can use the wrist-wearable device 680 to initiate a camera of the AR device 700, and the user can use the wrist-wearable device 680, the AR device 700, and/or the HIPD 690 to manipulate the image capture (e.g., zoom in or out, apply filters, etc.) and capture image data.

Turning to FIGS. 6B-1 and 6B-2, the user 602 is shown wearing the wrist-wearable device 680 and a VR device 710, and holding the HIPD 690. In the third AR system 600c, the wrist-wearable device 680, the VR device 710, and/or the HIPD 690 are used to interact within an AR environment, such as a VR game or other AR application. While the VR device 710 present a representation of a VR game (e.g., first AR game environment 620) to the user 602, the wrist-wearable device 680, the VR device 710, and/or the HIPD 690 detect and coordinate one or more user inputs to allow the user 602 to interact with the VR game.

In some embodiments, the user 602 can provide a user input via the wrist-wearable device 680, the VR device 710, and/or the HIPD 690 that causes an action in a corresponding AR environment. For example, the user 602 in the third AR system 600c (shown in FIG. 6B-1) raises the HIPD 690 to prepare for a swing in the first AR game environment 620. The VR device 710, responsive to the user 602 raising the HIPD 690, causes the AR representation of the user 622 to perform a similar action (e.g., raise a virtual object, such as a virtual sword 624). In some embodiments, each device uses respective sensor data and/or image data to detect the user input and provide an accurate representation of the user 602's motion. For example, image sensors (e.g., SLAM cameras or other cameras) of the HIPD 690 can be used to detect a position of the 690 relative to the user 602's body such that the virtual object can be positioned appropriately within the first AR game environment 620; sensor data from the wrist-wearable device 680 can be used to detect a velocity at which the user 602 raises the HIPD 690 such that the AR representation of the user 622 and the virtual sword 624 are synchronized with the user 602's movements; and image sensors 726 (FIGS. 7A-7C) of the VR device 710 can be used to represent the user 602's body, boundary conditions, or real-world objects within the first AR game environment 620.

In FIG. 6B-2, the user 602 performs a downward swing while holding the HIPD 690. The user 602's downward swing is detected by the wrist-wearable device 680, the VR device 710, and/or the HIPD 690 and a corresponding action is performed in the first AR game environment 620. In some embodiments, the data captured by each device is used to improve the user's experience within the AR environment. For example, sensor data of the wrist-wearable device 680 can be used to determine a speed and/or force at which the downward swing is performed and image sensors of the HIPD 690 and/or the VR device 710 can be used to determine a location of the swing and how it should be represented in the first AR game environment 620, which, in turn, can be used as inputs for the AR environment (e.g., game mechanics, which can use detected speed, force, locations, and/or aspects of the user 602's actions to classify a user's inputs (e.g., user performs a light strike, hard strike, critical strike, glancing strike, miss) or calculate an output (e.g., amount of damage)).

While the wrist-wearable device 680, the VR device 710, and/or the HIPD 690 are described as detecting user inputs, in some embodiments, user inputs are detected at a single device (with the single device being responsible for distributing signals to the other devices for performing the user input). For example, the HIPD 690 can operate an application for generating the first AR game environment 620 and provide the VR device 710 with corresponding data for causing the presentation of the first AR game environment 620, as well as detect the 602's movements (while holding the HIPD 690) to cause the performance of corresponding actions within the first AR game environment 620. Additionally or alternatively, in some embodiments, operational data (e.g., sensor data, image data, application data, device data, and/or other data) of one or more devices is provide to a single device (e.g., the HIPD 690) to process the operational data and cause respective devices to perform an action associated with processed operational data.

Having discussed example AR systems, devices for interacting with such AR systems, and other computing systems more generally, will now be discussed in greater detail below. Some definitions of devices and components that can be included in some or all of the example devices discussed below are defined here for ease of reference. A skilled artisan will appreciate that certain types of the components described below may be more suitable for a particular set of devices, and less suitable for a different set of devices. But subsequent reference to the components defined here should be considered to be encompassed by the definitions provided.

In some embodiments discussed below example devices and systems, including electronic devices and systems, will be discussed. Such example devices and systems are not intended to be limiting, and one of skill in the art will understand that alternative devices and systems to the example devices and systems described herein may be used to perform the operations and construct the systems and device that are described herein.

As described herein, an electronic device is a device that uses electrical energy to perform a specific function. It can be any physical object that contains electronic components such as transistors, resistors, capacitors, diodes, and integrated circuits. Examples of electronic devices include smartphones, laptops, digital cameras, televisions, gaming consoles, and music players, as well as the example electronic devices discussed herein. As described herein, an intermediary electronic device is a device that sits between two other electronic devices, and/or a subset of components of one or more electronic devices and facilitates communication, and/or data processing and/or data transfer between the respective electronic devices and/or electronic components.

### Example Head-Wearable Devices

FIGS. 7A, 7B-1, 7B-2, and 7C show example head-wearable devices, in accordance with some embodiments. Head-wearable devices can include, but are not limited to, AR devices 710 (e.g., AR or smart eyewear devices, such as smart glasses, smart monocles, smart contacts, etc.), VR devices 710 (e.g., VR headsets, head-mounted displays (HMD) s, etc.), or other ocularly coupled devices. The AR devices 700 and the VR devices 710 are instances of the head-wearable device 110 described in reference to FIGS. 1A-5 herein, such that the head-wearable device should be understood to have the features of the AR devices 700 and/or the VR devices 710, and vice versa. The AR devices 700 and the VR devices 710 can perform various functions and/or operations associated with navigating through user interfaces and selectively opening applications, as well as the functions and/or operations described above with reference to FIGS. 1A-5.

In some embodiments, an AR system (e.g., AR systems 600a-600b; FIGS. 6A-6B-2) includes an AR device 700 (as shown in FIG. 7A) and/or VR device 710 (as shown in FIGS. 7B-1-B-2). In some embodiments, the AR device 700 and the VR device 710 can include one or more analogous components (e.g., components for presenting interactive artificial-reality environments, such as processors, memory, and/or presentation devices, including one or more displays and/or one or more waveguides), some of which are described in more detail with respect to FIG. 7C. The head-wearable devices can use display projectors (e.g., display projector assemblies 707A and 707B) and/or waveguides for projecting representations of data to a user. Some embodiments of head-wearable devices do not include displays.

FIG. 7A shows an example visual depiction of the AR device 700 (e.g., which may also be described herein as augmented-reality glasses and/or smart glasses). The AR device 700 can work in conjunction with additional electronic components that are not shown in FIGS. 7A, such as a wearable accessory device and/or an intermediary processing device, in electronic communication or otherwise configured to be used in conjunction with the AR device 700. In some embodiments, the wearable accessory device and/or the intermediary processing device may be configured to couple with the AR device 700 via a coupling mechanism in electronic communication with a coupling sensor 724, where the coupling sensor 724 can detect when an electronic device becomes physically or electronically coupled with the AR device 700. In some embodiments, the AR device 700 can be configured to couple to a housing (e.g., a portion of frame 704 or temple arms 705), which may include one or more additional coupling mechanisms configured to couple with additional accessory devices. The components shown in FIG. 7A can be implemented in hardware, software, firmware, or a combination thereof, including one or more signal-processing components and/or application-specific integrated circuits (ASICs).

The AR device 700 includes mechanical glasses components, including a frame 704 configured to hold one or more lenses (e.g., one or both lenses 706-1 and 706-2). One of ordinary skill in the art will appreciate that the AR device 700 can include additional mechanical components, such as hinges configured to allow portions of the frame 704 of the AR device 700 to be folded and unfolded, a bridge configured to span the gap between the lenses 706-1 and 706-2 and rest on the user's nose, nose pads configured to rest on the bridge of the nose and provide support for the AR device 700, earpieces configured to rest on the user's ears and provide additional support for the AR device 700, temple arms 705 configured to extend from the hinges to the earpieces of the AR device 700, and the like. One of ordinary skill in the art will further appreciate that some examples of the AR device 700 can include none of the mechanical components described herein. For example, smart contact lenses configured to present artificial-reality to users may not include any components of the AR device 700.

The lenses 706-1 and 706-2 can be individual displays or display devices (e.g., a waveguide for projected representations). The lenses 706-1 and 706-2 may act together or independently to present an image or series of images to a user. In some embodiments, the lenses 706-1 and 706-2 can operate in conjunction with one or more display projector assemblies 707A and 707B to present image data to a user. While the AR device 700 includes two displays, embodiments of this disclosure may be implemented in AR devices with a single near-eye display (NED) or more than two NEDs.

The AR device 700 includes electronic components, many of which will be described in more detail below with respect to FIG. 7C. Some example electronic components are illustrated in FIG. 7A, including sensors 723-1, 723-2, 723-3, 723-4, 723-5, and 723-6, which can be distributed along a substantial portion of the frame 704 of the AR device 700. The different types of sensors are described below in reference to FIG. 7C. The AR device 700 also includes a left camera 739A and a right camera 739B, which are located on different sides of the frame 704. And the eyewear device includes one or more processors 748A and 748B (e.g., an integral microprocessor, such as an ASIC) that is embedded into a portion of the frame 704.

FIGS. 7B-1 and 7B-2 show an example visual depiction of the VR device 710 (e.g., a head-mounted display (HMD) 712, also referred to herein as an artificial-reality headset, a head-wearable device, a VR headset, etc.). The HMD 712 includes a front body 714 and a frame 716 (e.g., a strap or band) shaped to fit around a user's head. In some embodiments, the front body 714 and/or the frame 716 includes one or more electronic elements for facilitating presentation of and/or interactions with an AR and/or VR system (e.g., displays, processors (e.g., processor 748A-1), IMUs, tracking emitter or detectors, sensors, etc.). In some embodiments, the HMD 712 includes output audio transducers (e.g., an audio transducer 718-1), as shown in FIG. 7B-2. In some embodiments, one or more components, such as the output audio transducer(s) 718-1 and the frame 716, can be configured to attach and detach (e.g., are detachably attachable) to the HMD 712 (e.g., a portion or all of the frame 716, and/or the output audio transducer 718-1), as shown in FIG. 7B-2. In some embodiments, coupling a detachable component to the HMD 712 causes the detachable component to come into electronic communication with the HMD 712. The VR device 710 includes electronic components, many of which will be described in more detail below with respect to FIG. 7C.

FIG. 7B-1 to 7B-2 also show that the VR device 710 one or more cameras, such as the left camera 739A and the right camera 739B, which can be analogous to the left and right cameras on the frame 704 of the AR device 700. In some embodiments, the VR device 710 includes one or more additional cameras (e.g., cameras 739C and 739D), which can be configured to augment image data obtained by the cameras 739A and 739B by providing more information. For example, the camera 739C can be used to supply color information that is not discerned by cameras 739A and 739B. In some embodiments, one or more of the cameras 739A to 739D can include an optional IR cut filter configured to remove IR light from being received at the respective camera sensors.

The VR device 710 can include a housing 790 storing one or more components of the VR device 710 and/or additional components of the VR device 710. The housing 790 can be a modular electronic device configured to couple with the VR device 710 (or an AR device 700) and supplement and/or extend the capabilities of the VR device 710 (or an AR device 700). For example, the housing 790 can include additional sensors, cameras, power sources, processors (e.g., processor 748A-2), etc. to improve and/or increase the functionality of the VR device 710. Examples of the different components included in the housing 790 are described below in reference to FIG. 7C.

Alternatively, or in addition, in some embodiments, the head-wearable device, such as the VR device 710 and/or the AR device 700), includes, or is communicatively coupled to, another external device (e.g., a paired device), such as an HIPD, and/or an optional neckband. The optional neckband can couple to the head-wearable device via one or more connectors (e.g., wired or wireless connectors). The head-wearable device and the neckband can operate independently without any wired or wireless connection between them. In some embodiments, the components of the head-wearable device and the neckband are located on one or more additional peripheral devices paired with the head-wearable device, the neckband, or some combination thereof. Furthermore, the neckband is intended to represent any suitable type or form of paired device. Thus, the following discussion of neckband may also apply to various other paired devices, such as smart watches, smart phones, wrist bands, other wearable devices, hand-held controllers, tablet computers, or laptop computers.

In some situations, pairing external devices, such as an intermediary processing device (e.g., an HIPD device 690, an optional neckband, and/or wearable accessory device) with the head-wearable devices (e.g., an AR device 700 and/or VR device 710) enables the head-wearable devices to achieve a similar form factor of a pair of glasses while still providing sufficient battery and computation power for expanded capabilities. Some, or all, of the battery power, computational resources, and/or additional features of the head-wearable devices can be provided by a paired device or shared between a paired device and the head-wearable devices, thus reducing the weight, heat profile, and form factor of the head-wearable devices overall while allowing the head-wearable devices to retain its desired functionality. For example, the intermediary processing device (e.g., the HIPD 690) can allow components that would otherwise be included in a head-wearable device to be included in the intermediary processing device (and/or a wearable device or accessory device), thereby shifting a weight load from the user's head and neck to one or more other portions of the user's body. In some embodiments, the intermediary processing device has a larger surface area over which to diffuse and disperse heat to the ambient environment. Thus, the intermediary processing device can allow for greater battery and computation capacity than might otherwise have been possible on the head-wearable devices, standing alone. Because weight carried in the intermediary processing device can be less invasive to a user than weight carried in the head-wearable devices, a user may tolerate wearing a lighter eyewear device and carrying or wearing the paired device for greater lengths of time than the user would tolerate wearing a heavier eyewear device standing alone, thereby enabling an artificial-reality environment to be incorporated more fully into a user's day-to-day activities.

In some embodiments, the intermediary processing device is communicatively coupled with the head-wearable device and/or to other devices. The other devices may provide certain functions (e.g., tracking, localizing, depth mapping, processing, storage, etc.) to the head-wearable device. In some embodiments, the intermediary processing device includes a controller and a power source. In some embodiments, sensors of the intermediary processing device are configured to sense additional data that can be shared with the head-wearable devices in an electronic format (analog or digital).

The controller of the intermediary processing device processes information generated by the sensors on the intermediary processing device and/or the head-wearable devices. The intermediary processing device, like an HIPD 690, can process information generated by one or more sensors of its sensors and/or information provided by other communicatively coupled devices. For example, a head-wearable device can include an IMU, and the intermediary processing device (neckband and/or an HIPD 690) can compute all inertial and spatial calculations from the IMUs located on the head-wearable device.

Artificial-reality systems may include a variety of types of visual feedback mechanisms. For example, display devices in the AR devices 700 and/or the VR devices 710 may include one or more liquid-crystal displays (LCDs), light emitting diode (LED) displays, organic LED (OLED) displays, and/or any other suitable type of display screen. Artificial-reality systems may include a single display screen for both eyes or may provide a display screen for each eye, which may allow for additional flexibility for varifocal adjustments or for correcting a refractive error associated with the user's vision. Some artificial-reality systems also include optical subsystems having one or more lenses (e.g., conventional concave or convex lenses, Fresnel lenses, or adjustable liquid lenses) through which a user may view a display screen. In addition to or instead of using display screens, some artificial-reality systems include one or more projection systems. For example, display devices in the AR device 700 and/or the VR device 710 may include micro-LED projectors that project light (e.g., using a waveguide) into display devices, such as clear combiner lenses that allow ambient light to pass through. The display devices may refract the projected light toward a user's pupil and may enable a user to simultaneously view both artificial-reality content and the real world. Artificial-reality systems may also be configured with any other suitable type or form of image projection system. As noted, some AR systems may, instead of blending an artificial reality with actual reality, substantially replace one or more of a user's sensory perceptions of the real world with a virtual experience.

While the example head-wearable devices are respectively described herein as the AR device 700 and the VR device 710, either or both of the example head-wearable devices described herein can be configured to present fully-immersive VR scenes presented in substantially all of a user's field of view, additionally or alternatively to, subtler augmented-reality scenes that are presented within a portion, less than all, of the user's field of view.

In some embodiments, the AR device 700 and/or the VR device 710 can include haptic feedback systems. The haptic feedback systems may provide various types of cutaneous feedback, including vibration, force, traction, shear, texture, and/or temperature. The haptic feedback systems may also provide various types of kinesthetic feedback, such as motion and compliance. The haptic feedback can be implemented using motors, piezoelectric actuators, fluidic systems, and/or a variety of other types of feedback mechanisms. The haptic feedback systems may be implemented independently of other artificial-reality devices, within other artificial-reality devices, and/or in conjunction with other artificial-reality devices (e.g., wrist-wearable devices which may be incorporated into headwear, gloves, body suits, handheld controllers, environmental devices (e.g., chairs or floormats), and/or any other type of device or system, such as a wrist-wearable device 680, an HIPD 690, smart textile-based garment, etc.), and/or other devices described herein.

FIG. 7C illustrates a computing system 720 and an optional housing 790, each of which show components that can be included in a head-wearable device (e.g., the AR device 700 and/or the VR device 710). In some embodiments, more or less components can be included in the optional housing 790 depending on practical restraints of the respective head-wearable device being described. Additionally, or alternatively, the optional housing 790 can include additional components to expand and/or augment the functionality of a head-wearable device.

In some embodiments, the computing system 720 and/or the optional housing 790 can include one or more peripheral interfaces 722A and 722B, one or more power systems 742A and 742B (including charger input 743, PMIC 744, and battery 745), one or more controllers 746A 746B (including one or more haptic controllers 747), one or more processors 748A and 748B (as defined above, including any of the examples provided), and memory 750A and 750B, which can all be in electronic communication with each other. For example, the one or more processors 748A and/or 748B can be configured to execute instructions stored in the memory 750A and/or 750B, which can cause a controller of the one or more controllers 746A and/or 746B to cause operations to be performed at one or more peripheral devices of the peripherals interfaces 722A and/or 722B. In some embodiments, each operation described can occur based on electrical power provided by the power system 742A and/or 742B.

In some embodiments, the peripherals interface 722A can include one or more devices configured to be part of the computing system 720. For example, the peripherals interface can include one or more sensors 723A. Some example sensors include: one or more coupling sensors 724, one or more acoustic sensors 725, one or more imaging sensors 726, one or more EMG sensors 727, one or more capacitive sensors 728, and/or one or more IMUs 729. In some embodiments, the sensors 723A further include depth sensors 767, light sensors 768 and/or any other types of sensors defined above or described with respect to any other embodiments discussed herein.

In some embodiments, the peripherals interface can include one or more additional peripheral devices, including one or more NFC devices 730, one or more GPS devices 731, one or more LTE devices 732, one or more WiFi and/or Bluetooth devices 733, one or more buttons 734 (e.g., including buttons that are slidable or otherwise adjustable), one or more displays 735A, one or more speakers 736A, one or more microphones 737A, one or more cameras 738A (e.g., including the a first camera 739-1 through nth camera 739-n, which are analogous to the left camera 739A and/or the right camera 739B), one or more haptic devices 740; and/or any other types of peripheral devices defined above or described with respect to any other embodiments discussed herein.

The head-wearable devices can include a variety of types of visual feedback mechanisms (e.g., presentation devices). For example, display devices in the AR device 700 and/or the VR device 710 can include one or more liquid-crystal displays (LCDs), light emitting diode (LED) displays, organic LED (OLED) displays, micro-LEDs, and/or any other suitable types of display screens. The head-wearable devices can include a single display screen (e.g., configured to be seen by both eyes), and/or can provide separate display screens for each eye, which can allow for additional flexibility for varifocal adjustments and/or for correcting a refractive error associated with the user's vision. Some embodiments of the head-wearable devices also include optical subsystems having one or more lenses (e.g., conventional concave or convex lenses, Fresnel lenses, or adjustable liquid lenses) through which a user can view a display screen. For example, respective displays 735A can be coupled to each of the lenses 706-1 and 706-2 of the AR device 700. The displays 735A coupled to each of the lenses 706-1 and 706-2 can act together or independently to present an image or series of images to a user. In some embodiments, the AR device 700 and/or the VR device 710 includes a single display 735A (e.g., a near-eye display) or more than two displays 735A.

In some embodiments, a first set of one or more displays 735A can be used to present an augmented-reality environment, and a second set of one or more display devices 735A can be used to present a virtual-reality environment. In some embodiments, one or more waveguides are used in conjunction with presenting artificial-reality content to the user of the AR device 700 and/or the VR device 710 (e.g., as a means of delivering light from a display projector assembly and/or one or more displays 735A to the user's eyes). In some embodiments, one or more waveguides are fully or partially integrated into the AR device 700 and/or the VR device 710. Additionally, or alternatively to display screens, some artificial-reality systems include one or more projection systems. For example, display devices in the AR device 700 and/or the VR device 710 can include micro-LED projectors that project light (e.g., using a waveguide) into display devices, such as clear combiner lenses that allow ambient light to pass through. The display devices can refract the projected light toward a user's pupil and can enable a user to simultaneously view both artificial-reality content and the real world. The head-wearable devices can also be configured with any other suitable type or form of image projection system. In some embodiments, one or more waveguides are provided additionally or alternatively to the one or more display(s) 735A.

In some embodiments of the head-wearable devices, ambient light and/or a real-world live view (e.g., a live feed of the surrounding environment that a user would normally see) can be passed through a display element of a respective head-wearable device presenting aspects of the AR system. In some embodiments, ambient light and/or the real-world live view can be passed through a portion less than all, of an AR environment presented within a user's field of view (e.g., a portion of the AR environment co-located with a physical object in the user's real-world environment that is within a designated boundary (e.g., a guardian boundary) configured to be used by the user while they are interacting with the AR environment). For example, a visual user interface element (e.g., a notification user interface element) can be presented at the head-wearable devices, and an amount of ambient light and/or the real-world live view (e.g., 15-50% of the ambient light and/or the real-world live view) can be passed through the user interface element, such that the user can distinguish at least a portion of the physical environment over which the user interface element is being displayed.

The head-wearable devices can include one or more external displays 735A for presenting information to users. For example, an external display 735A can be used to show a current battery level, network activity (e.g., connected, disconnected, etc.), current activity (e.g., playing a game, in a call, in a meeting, watching a movie, etc.), and/or other relevant information. In some embodiments, the external displays 735A can be used to communicate with others. For example, a user of the head-wearable device can cause the external displays 735A to present a do not disturb notification. The external displays 735A can also be used by the user to share any information captured by the one or more components of the peripherals interface 722A and/or generated by head-wearable device (e.g., during operation and/or performance of one or more applications).

The memory 750A can include instructions and/or data executable by one or more processors 748A (and/or processors 748B of the housing 790) and/or a memory controller of the one or more controllers 746A (and/or controller 746B of the housing 790). The memory 750A can include one or more operating systems 751; one or more applications 752; one or more communication interface modules 753A; one or more graphics modules 754A; one or more AR processing modules 755A; one or more thermal management modules 756A for performing the functions and/or operations described above with reference to FIGS. 1A-5; and/or any other types of modules or components defined above or described with respect to any other embodiments discussed herein.

The data 760 stored in memory 750A can be used in conjunction with one or more of the applications and/or programs discussed above. The data 760 can include profile data 761; sensor data 762; media content data 763; AR application data 764; thermal management data 765 for storing data related to the functions and/or operations described above with reference to FIGS. 1A-5; and/or any other types of data defined above or described with respect to any other embodiments discussed herein.

In some embodiments, the controller 746A of the head-wearable devices processes information generated by the sensors 723A on the head-wearable devices and/or another component of the head-wearable devices and/or communicatively coupled with the head-wearable devices (e.g., components of the housing 790, such as components of peripherals interface 722B). For example, the controller 746A can process information from the acoustic sensors 725 and/or image sensors 726. For each detected sound, the controller 746A can perform a direction of arrival (DOA) estimation to estimate a direction from which the detected sound arrived at a head-wearable device. As one or more of the acoustic sensors 725 detects sounds, the controller 746A can populate an audio data set with the information (e.g., represented by sensor data 762).

In some embodiments, a physical electronic connector can convey information between the head-wearable devices and another electronic device, and/or between one or more processors 748A of the head-wearable devices and the controller 746A. The information can be in the form of optical data, electrical data, wireless data, or any other transmittable data form. Moving the processing of information generated by the head-wearable devices to an intermediary processing device can reduce weight and heat in the eyewear device, making it more comfortable and safer for a user. In some embodiments, an optional accessory device (e.g., an electronic neckband or an HIPD 690) is coupled to the head-wearable devices via one or more connectors. The connectors can be wired or wireless connectors and can include electrical and/or non-electrical (e.g., structural) components. In some embodiments, the head-wearable devices and the accessory device can operate independently without any wired or wireless connection between them.

The head-wearable devices can include various types of computer vision components and subsystems. For example, the AR device 700 and/or the VR device 710 can include one or more optical sensors such as two-dimensional (2D) or three-dimensional (3D) cameras, time-of-flight depth sensors, single-beam or sweeping laser rangefinders, 3D LiDAR sensors, and/or any other suitable type or form of optical sensor. A head-wearable device can process data from one or more of these sensors to identify a location of a user and/or aspects of the use's real-world physical surroundings, including the locations of real-world objects within the real-world physical surroundings. In some embodiments, the methods described herein are used to map the real world, to provide a user with context about real-world surroundings, and/or to generate interactable virtual objects (which can be replicas or digital twins of real-world objects that can be interacted with in AR environment), among a variety of other functions. For example, FIGS. 7B-1 and 7B-2 show the VR device 710 having cameras 739A-739D, which can be used to provide depth information for creating a voxel field and a two-dimensional mesh to provide object information to the user to avoid collisions.

The optional housing 790 can include analogous components to those describe above with respect to the computing system 720. For example, the optional housing 790 can include a respective peripherals interface 722B including more or less components to those described above with respect to the peripherals interface 722A. As described above, the components of the optional housing 790 can be used augment and/or expand on the functionality of the head-wearable devices. For example, the optional housing 790 can include respective sensors 723B, speakers 736B, displays 735B, microphones 737B, cameras 738B, and/or other components to capture and/or present data. Similarly, the optional housing 790 can include one or more processors 748B, controllers 746B, and/or memory 750B (including respective communication interface modules 753B; one or more graphics modules 754B; one or more AR processing modules 755B, etc.) that can be used individually and/or in conjunction with the components of the computing system 720.

The techniques described above in FIGS. 7A-7C can be used with different head-wearable devices. In some embodiments, the head-wearable devices (e.g., the AR device 700 and/or the VR device 710) can be used in conjunction with one or more wearable device such as a wrist-wearable device 680 (or components thereof). Having thus described example the head-wearable devices, attention will now be turned to example handheld intermediary processing devices, such as HIPD 690.

Any data collection performed by the devices described herein and/or any devices configured to perform or cause the performance of the different embodiments described above in reference to any of the Figures, hereinafter the “devices,” is done with user consent and in a manner that is consistent with all applicable privacy laws. Users are given options to allow the devices to collect data, as well as the option to limit or deny collection of data by the devices. A user is able to opt-in or opt-out of any data collection at any time. Further, users are given the option to request the removal of any collected data.

It will be understood that, although the terms “first,” “second,” etc. may be used herein to describe various elements, these elements should not be limited by these terms. These terms are only used to distinguish one element from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” can be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” can be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

What is claimed is:

1. A head-wearable device, comprising:
a housing including:
one or more electronics components, and
a user-facing surface; and
a passive cooling surface cover coupled to the user-facing surface of the housing such that, when the head-wearable device is worn, the passive-cooling surface cover contacts a portion of a user's body, wherein the passive cooling surface cover is configured to:
absorb heat generated by the one or more electronics components and transferred to the user-facing contact surface; and
evaporate a stored moisture using the heat generated by the one or more electronics components to decrease a temperature of the one or more electronics components and/or the passive cooling surface cover.

2. The head-wearable device of claim 1, wherein the passive cooling surface cover is further configured to absorb moisture from an environment and accumulate absorbed moisture with the stored moisture.

3. The head-wearable device of any one of claim 1, wherein the passive cooling surface cover includes at least two states, wherein the at least two states includes a collapsed state and a swollen state.

4. The head-wearable device of any one of claim 1, wherein the passive cooling surface cover includes one or more sensors, the one or more sensors including one or more of a temperature sensor, a moisture sensor, and a chemical sensor.

5. The head-wearable device of claim 4, wherein the one or more electronics components includes one or more processors configured to execute one or more programs stored in memory communicatively coupled with the one or more processors, the one or more programs including instructions for:
monitoring sensor data provided by the one or more sensors; and
in accordance with a determination that the sensor data indicates that thermal management criteria are not satisfied, adjusting performance of at least one electronics component of the one or more electronics components.

6. The head-wearable device of claim 5, wherein the thermal management criteria include one or more of a head-wearable device thermal threshold, passive cooling surface cover thermal threshold, a passive cooling surface cover volume threshold, an electronics components specific thermal threshold, and a user skin temperature threshold.

7. The head-wearable device of any one of claim 1, wherein the passive cooling surface cover is disposed over one or more predetermined portions of the user-facing surface, the one or more predetermined portions of the user-facing surface corresponding to placement of one or more heat-dissipating components.

8. The head-wearable device of any one of claim 1, wherein the passive cooling surface cover includes one or more layers including a cooling material layer and an adhesive layer.

9. The head-wearable device of claim 8, wherein the adhesive layer is configured to couple with the user-facing surface and has a predetermined thermal conductivity.

10. The head-wearable device of any one of claim 8, wherein the cooling material layer includes a plurality of sublayers.

11. The head-wearable device of any one of claim 8, wherein the one or more layers includes a moisture-wicking layer, the cooling material layer disposed between the thermal interface layer and the moisture-wicking layer, wherein the moisture-wicking layer is configured to contact the portion of the user's body.

12. The head-wearable device of any one of claim 1, wherein the passive cooling surface cover includes:
a device coupling portion configured to couple to the user-facing surface of the housing;
a user coupling portion configured to contact the portion of the user's body; and
a ventilation portion configured to be exposed to an open environment.

13. The head-wearable device of claim 12, wherein the user coupling portion and/or the ventilation portion are non-smooth or non-continuous surfaces with different topological or micro-structures.

14. The head-wearable device of any one of claim 1, wherein the passive cooling surface cover is detachable from the housing or permanently affixed to the housing.

15. The head-wearable device of any one of claim 1, wherein the housing includes an exposed surface opposite the user-facing surface, and the head-wearable device comprises:
an additional passive cooling surface cover coupled to the exposed surface.

16. A non-transitory computer readable storage medium including instructions that, when executed by a computing device including one or more processors, cause the computing device to:
generate, by one or more electronics components, heat;
transfer the heat to a user-facing contact surface;
absorb, at a passive cooling surface cover, the heat generated by the one or more electronics components and transferred to the user-facing contact surface, wherein the passive cooling surface cover is coupled to the user-facing surface of a housing of a head-wearable device such that, when the head-wearable device is worn, the passive-cooling surface cover contacts a portion of a user's body; and
evaporate a stored moisture using the heat generated by the one or more electronics components to decrease a temperature of the one or more electronics components and/or the passive cooling surface cover.

17. The non-transitory computer readable storage medium of claim 16, wherein the passive cooling surface cover includes one or more sensors, the one or more sensors including one or more of a temperature sensor, a moisture sensor, and a chemical sensor.

18. The non-transitory computer readable storage medium of claim 17, wherein the instructions cause the one or more processors to:
monitor sensor data provided by the one or more sensors; and
in accordance with a determination that the sensor data indicates that thermal management criteria are not satisfied, adjust performance of at least one electronics component of the one or more electronics components.

19. The non-transitory computer readable storage medium of claim 18, wherein the thermal management criteria include one or more of a head-wearable device thermal threshold, passive cooling surface cover thermal threshold, a passive cooling surface cover volume threshold, an electronics components specific thermal threshold, and a user skin temperature threshold.

20. A method, comprising:
providing a housing including one or more electronic components and a user-facing surface, the one or more electronic components generating heat and transferring the heat to the user-facing surface;
provide a passive cooling surface cover coupled to the user-facing surface of the housing such that, when the housing is worn, the passive-cooling surface cover contracts a portion of a user's body;
absorbing the heat by the passive cooling surface cover; and
evaporating a stored moisture using the heat generated by the one or more electronics components to decrease a temperature of the one or more electronics components and/or the passive cooling surface cover.
